(19) United States
(12) Patent Application Publication
(10) Pub. No.: US 2018/0245445 A1
(43) Pub. Date: Aug. 30, 2018

(54) METHOD AND SYSTEM FOR MONITORING THE PERFORMANCE OF OIL AND/OR GAS DRILLING EQUIPMENT

(71) Applicant: SHELL OIL COMPANY, Houston, TX (US)

(72) Inventors: Winfried THEIS, Amsterdam (NL); Jesper Wilhelmus WENTINK, Rijswijk (NL); Jan-Jette BLANGÉ, Rijswijk (NL)

(21) Appl. No.: 15/755,202

(22) PCT Filed: Aug. 30, 2016
(86) PCT No.: PCT/US2016/049442

§ 371 Date: Feb. 26, 2018

(30) Foreign Application Priority Data
Aug. 31, 2015 (EP) 15183151.8

(51) Int. Cl. E21B 44/00; E21B 21/00; E21B 19/00; E21B 3/02; G01R 31/34; G01R 21/133

(52) U.S. Cl. CPC E21B 44/00; E21B 21/00; G01R 21/133; E21B 3/02; G01R 31/343; E21B 19/008

(57) ABSTRACT

The performance of oil/and or gas well drilling equipment is measured by: input and output performance sensor assemblies that monitor associated equipment input and output performance characteristics; and alerting an operator if there is an anomaly between the monitored input and output performance characteristics; and wherein furthermore electric or hydraulic power input characteristics supplied to drilling equipment, such as a mud pump, drill string hoist and top drive are compared with delivered output characteristics, such as mud flux, drill string weight and rotation to alert an operator if there is an anomaly between the measured input and output characteristics.

### BACKGROUND OF THE INVENTION

The invention relates to a method and system for monitoring the performance of oil/and or gas drilling equipment.

When rig equipment performance and/or integrity monitoring sensors are drifting, or a drilling machine is suffering from wear, the driller can only deduce from various symptoms what is going on.

There is therefore a need for an improved method and system for monitoring the performance of oil/and or gas drilling equipment that directly alerts an rig operator whether it is the monitored equipment (including the sensors) or whether it is the drilling assembly and/or power supply equipment that has a problem. This is particularly important for automated closed loop and other drilling systems such as applicant's Well Vantage (a Shell trade mark) and ScadaDrill projects.

At the moment, only rather limited input versus output parameter comparison systems are available on drilling rigs, such as a drilling fluid inflow rate flux into the well versus a drilling fluid outflow rate flux out of the well to monitor any progress of the drilling process, leakage of drilling fluid into the surrounding formation and/or a well kick associated with potential influx of formation fluid into the well.

Other known input-output parameter comparison systems are disclosed in US patent applications US2014/0326505, US2013/275100, US2004/124012 and US2003/065447. The latter prior art reference discloses a method to monitor the performance of reciprocating sucker rod pumps in sucker rod operated oil production wells, which involves another field of technology and is not an obvious prior art reference to consult for resolving the long standing problem of monitoring the performance of complex drilling equipment at a drilling rig.

The other prior art references only provide rather limited input-output parameter comparisons using e.g. video performance monitoring equipment.

There is a need for an improved method for monitoring the performance and optional malfunctioning of rig equipment at an oil/and or gas drilling facility.

Furthermore there is a need to improve drilling rig equipment quality control systems and to enable the early detection and localization of drilling rig equipment malfunctions.

Furthermore there is a need to provide an improved drilling equipment performance monitoring system to monitor any losses that go with the functionality of the equipment, wherein input/output anomalies, such as absolute or relative differences between input and output equipment performance characteristics, are monitored and compared to assess the associated drilling equipment performance and/or malfunctioning.

### SUMMARY OF THE INVENTION

In accordance with the invention there is provided a method for monitoring both the input and output performance of oil/and or gas well drilling equipment, the method comprising:

providing the equipment with input and output sensor assemblies for monitoring input and output equipment performance characteristics; and

alerting an operator if there is an anomaly between the monitored input and output performance characteristics;

characterized in that:

the equipment is electrically and/or hydraulically powered and comprises a hydraulic and/or mechanical output assembly;

the input sensor assembly monitors an electrical and/or hydraulic power consumption of the equipment;

the output sensor assembly monitors a delivered hydraulic and/or mechanical output performance of the output assembly; and

the operator is alerted if there is an anomaly between the monitored power consumption and delivered output performance.

The method may further comprise:

real time monitoring a power conversion efficiency of the equipment on the basis of the monitored power consumption and delivered output performance;

providing a model that estimates an estimated normal performance of the equipment; and

providing a deviation alert signal to an operator in case there is an anomaly between the monitored real time performance and the estimated normal performance of the equipment.

The equipment may comprise a drilling mud circulation assembly and the method may comprise using the input sensor assembly to monitor electric power supplied to an electric motor driving a mud circulation pump and comparing the monitored electric power supply with a hydraulic power output monitored by the output sensor assembly comprising mud flux pressure and mud velocity or mud flow rate sensors at an outlet of the mud circulation pump. The comparison between the monitored electric power supply and hydraulic power output may be used to monitor an efficiency of the electric to hydraulic energy conversion, malfunction and optionally a suboptimal performance of the mud circulation pump.

The equipment may comprise a drill string hoisting assembly and the input sensor assembly may be used to monitor a length of drill line unwound from a reeling drum and compared with an associated translation of a top drive suspended from the drill line monitored by the output sensor assembly and an alert may be provided to the operator if there is any difference between the monitored length and translation that exceeds a predetermined threshold. Furthermore a tension in a dead line anchor of the drill string hoisting assembly may be monitored by a tension sensor and compared with an estimated weight of a drill string to assess whether the tension sensor functions accurately.

The equipment may comprise a drill string rotation assembly and the method may further comprise:

using the input sensor assembly to monitor electric or hydraulic power input supplied to an electric or hydraulic top drive;

using the output sensor assembly to monitor delivered mechanical power output using drill string torque and drill string rotational speed near the top drive; and

providing an alert to the operator if there is an anomaly between the monitored supplied power input and delivered mechanical power output. In such case the method may be used to monitor whether the anomaly is generated by a technical problem at the top drive or whether, on the contrary, the top drive efficiency is acceptable but the drill string or an associated drill bit and/or bottom hole drilling assembly has a technical malfunction.

In accordance with the invention there is furthermore provided a system for monitoring the performance of oil/and or gas well drilling equipment comprising a computer readable medium, which, when connected to a computer, induces the computer to execute the method according to the invention.

The system may comprise:

input and output performance sensor assemblies for monitoring associated input and output equipment performance characteristics of the equipment; and

a user interface configured to alert an operator if there is an anomaly between the performance monitored by the input and output performance sensor assemblies. The equipment may be electrically and/or hydraulically powered and:

the input and output performance sensor assemblies are configured to monitor a power conversion efficiency of the equipment on a real time basis;

a model is configured to assess an estimated normal power conversion efficiency of the equipment; and

a user interface is configured to provide a deviation alert signal to an operator in case an anomaly between the real time power conversion efficiency monitored by the dedicated performance sensors and the estimated normal power conversion efficiency exceeds a predetermined value.

The equipment may comprise drilling equipment at a rig for the drilling of a crude oil and/or natural gas exploration and/or production well, and may be controlled by an automated closed loop control system with a selected set-point and the system may be configured to automatically adjust the set point in response to the anomaly and alert an operator about the anomaly and the set-point adjustment.

The system according to the invention may be configured to compare electrical or hydraulic power input characteristics supplied to drilling equipment, including a mud pump, drill string hoist and top drive with delivered output drilling characteristics, including mud flux, drill string weight and rotation to alert an operator if there is an anomaly between any of the measured input and output characteristics.

These and other features, embodiments and advantages of the method and system according to the invention are described in the accompanying claims, abstract and the following detailed description of a non-limiting embodiment depicted in the accompanying drawing, in which description reference numerals are used which refer to corresponding reference numerals that are depicted in the drawing.

Objects and other features depicted in the figure and/or described in this specification, abstract and/or claims may be combined in different ways by a person skilled in the art.

### BRIEF DESCRIPTION OF THE DRAWING

FIG. 1 shows a drilling rig where the deadline anchor tension sensor measurement is compared with weight of the drill string to alert an operator about any anomaly in accordance with the invention.

### DETAILED DESCRIPTION OF THE DEPICTED EMBODIMENT

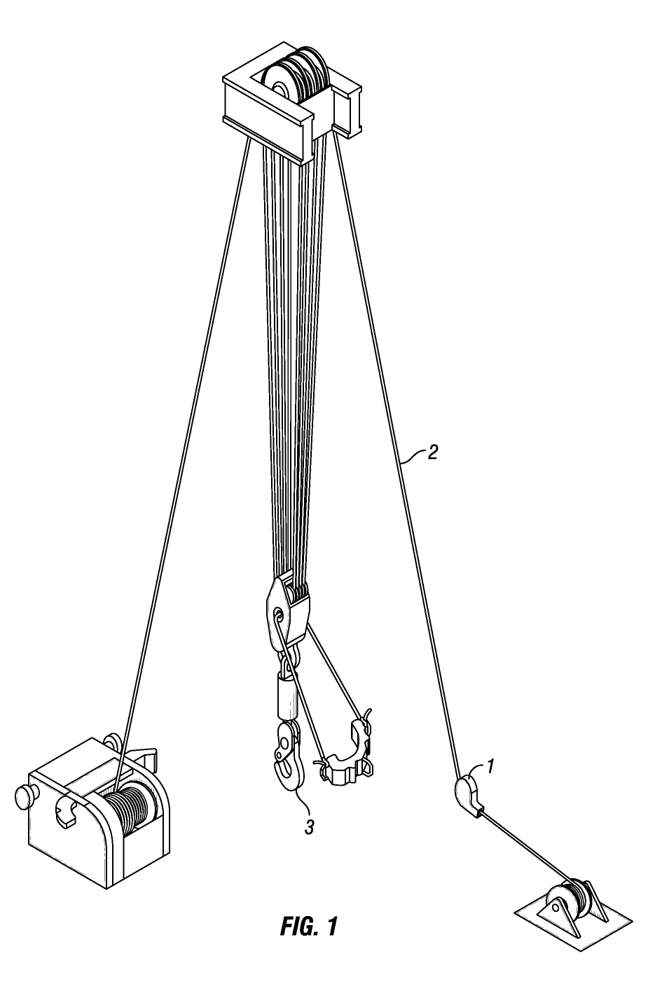

FIG. 1 shows a drilling rig where the tension in the deadline (2) is measured by a deadline anchor tension sensor (1) and is compared with the weight of the drill string (not shown) suspended from the drilling hook (3), taking into account the known gearing ratio provided by the amount of windings of the hoist cable between the crown block and travelling block.

In accordance with the invention a drilling operator is alerted if there is a significant absolute or relative anomaly during a significant period of time between the known weight of the drill string suspended from the drilling hook (3) and the hoisting line tension measured by the deadline anchor tension sensor (1) and the known gearing ratio.

Various other machines on drilling rigs require power and material passing through in order to perform its function. Drilling pumps for instance require electricity in order to pressure the drilling fluid entering the device. Currently, drilling rigs rely on scheduled calibration of the sensors and do not make use of a sanity check of the data the rig sensor system is generating. An effective method for this would be to compare a conserved physical parameter (correlated with the system performance) at the input and on the output side of the system.

Generally, the system according to the invention may be configured to compare electrical or hydraulic power input characteristics supplied to drilling equipment, including a mud pump, drill string hoist and top drive with delivered output drilling characteristics, including mud flux, drill string weight and rotation to alert an operator if there is an anomaly between any of the measured input and output characteristics.

Some illustrative examples I-IV are provided below:

I. measurement of electric power to the motors driving the mud pumps and compare with the hydraulic power at the outlet of the mud pumps. By monitoring the efficiency of the energy conversion, malfunction or suboptimal performance of the rig pump installation can be identified or excluded as a cause of unexpected values.

II. The length of drill line unwound from the drum should correspond to a specific translation of the topdrive.

III. Electric power to an electric topdrive or hydraulic power to a hydraulic top drive should correspond with an acceptable efficiency to the mechanical power (based on torque and string rotational speed) driving the drill string. Monitoring this efficiency shows for instance whether a technical problem is emerging at the top drive or whether, on the contrary, the top drive efficiency is okay but, for instance, the drill string may have a technical malfunction.

IV. The tension in the dead line anchor measured by the tension sensor(1) can be compared to the known weight of the drill string as illustrated in FIG. 1.

The method and system according to the invention may also be used in a closed loop control environment by taking actual operational efficiency into account in well construction modelling, software supporting closed loop control modules and/or supporting a rig operation monitoring center.

Therefore, the method and system according to present invention are well adapted to attain the ends and advantages mentioned as well as those that are inherent therein.

The particular embodiments disclosed above are illustrative only, as the present invention may be modified, combined and/or practiced in different but equivalent manners apparent to those skilled in the art having the benefit of the teachings herein.

Furthermore, no limitations are intended to the details of construction or design herein shown, other than as described in the claims below.

It is therefore evident that the particular illustrative embodiments disclosed above may be altered, combined and/or modified and all such variations are considered within the scope of the present invention as defined in the accompanying claims.

While any methods, systems and/or products embodying the invention are described in terms of “comprising,” “containing,” or “including” various described features and/or steps, they can also “consist essentially of” or “consist of” the various described features and steps.

All numbers and ranges disclosed above may vary by some amount. Whenever a numerical range with a lower limit and an upper limit is disclosed, any number and any included range falling within the range is specifically disclosed. In particular, every range of values (of the form, “from about a to about b,” or, equivalently, “from approximately a to b,” or, equivalently, “from approximately a-b”) disclosed herein is to be understood to set forth every number and range encompassed within the broader range of values.

Also, the terms in the claims have their plain, ordinary meaning unless otherwise explicitly and clearly defined by the patentee.

Moreover, the indefinite articles “a” or “an”, as used in the claims, are defined herein to mean one or more than one of the element that it introduces.

If there is any conflict in the usages of a word or term in this specification and one or more patent or other documents that may be cited herein by reference, the definitions that are consistent with this specification should be adopted.

Accordingly it will be understood that the invention provides an improved method and system for monitoring the performance of oil/and or gas drilling equipment comprising:

providing the equipment with a plurality of input and output performance sensors for monitoring input and output equipment performance parameters; and

alerting an operator if there is a deviation between the performance monitored by input and output performance sensors.

Optionally the power supplied to electrically or hydraulically driven drilling rig equipment, such as a mud pump and/or a drill string hoist and/or top drive is monitored real time and compared with mud flux measurements and/or drill string weight and motion measurements to alert an operator if there is any significant anomaly between the monitored input and output equipment performance parameters.

1. A method for monitoring both the input and output performance of oil and/or gas well drilling equipment, the method comprising:
providing the equipment with input and output sensor assemblies for monitoring input and output equipment performance characteristics; and
alerting an operator if there is an anomaly between the monitored input and output performance characteristics;
wherein:
the equipment and comprises a power output assembly;
the input sensor assembly monitors a power consumption of the equipment;
the output sensor assembly monitors a delivered output performance of the output assembly; and
the operator is alerted if there is an anomaly between the monitored power consumption and delivered power output performance

2. The method of claim 1, wherein the method further comprises:
real time monitoring a power conversion efficiency of the equipment on the basis of the monitored power consumption and delivered power output performance;
providing a model that estimates an estimated normal performance of the equipment; and
providing a deviation alert signal to an operator in case there is an anomaly between a monitored real time performance and the estimated normal performance of the equipment.

3. The method of claim 1, wherein the equipment comprises a drilling mud circulation assembly and the method comprises using the input sensor assembly to monitor electric power supplied to an electric motor driving a mud circulation pump and comparing the monitored electric power supply with a hydraulic power output monitored by the output sensor assembly comprising mud flux pressure and mud velocity or mud flow rate sensors at an outlet of the mud circulation pump.

4. The method of claim 3, wherein the method further comprises using the comparison between the monitored electric power supply and hydraulic power output to monitor an efficiency of the electric to hydraulic energy conversion, malfunction and optionally a suboptimal performance of the mud circulation pump.

5. The method of claim 1, wherein the equipment comprises a drill string hoisting assembly and the input sensor assembly is used to monitor a length of drill line unwound from a reeling drum and compared with an associated translation of a top drive suspended from the drill line monitored by the output sensor assembly and an alert is provided to the operator if there is any difference between the monitored length and translation that exceeds a predetermined threshold.

6. The method of claim 5, wherein furthermore a tension in a dead line anchor of the drill string hoisting assembly is monitored by a tension sensor and is compared with an estimated weight of a drill string to assess whether the tension sensor functions accurately.

7. The method of claim 1, wherein the equipment comprises a drill string rotation assembly and the method further comprises:
using the input sensor assembly to monitor power input supplied to a top drive;
using the output sensor assembly to monitor delivered mechanical power output using drill string torque and drill string rotational speed near the top drive; and
providing an alert to the operator if there is an anomaly between the monitored supplied power input and delivered mechanical power output .

8. The method of claim 7, wherein the method is used to monitor whether the anomaly is generated by a technical problem at the top drive or whether, on the contrary, the top drive efficiency is acceptable but the drill string or an associated drill bit and/or bottom hole drilling assembly has a technical malfunction.

9. A system for monitoring the performance of oil and/or gas well drilling equipment comprising a computer readable medium, which, when connected to a computer, induces the computer to execute the method according to claim 1.

10. The system of claim 9, wherein the system further comprises:
input and output performance sensor assemblies for monitoring associated input and output equipment performance characteristics of the equipment; and
a user interface configured to alert an operator if there is an anomaly between the performance monitored by the input and output performance sensor assemblies.

11. The system of claim 10, wherein:
the input and output performance sensor assemblies are configured to monitor a power conversion efficiency of the equipment on a real time basis;
a model is configured to assess an estimated normal power conversion efficiency of the equipment; and
a user interface is configured to provide a deviation alert signal to an operator in case an anomaly between a real time power conversion efficiency monitored by the dedicated performance sensors and the estimated normal power conversion efficiency exceeds a predetermined value.

12. The system of claim 9, wherein the oil and/or gas drilling equipment comprises drilling equipment at a rig for the drilling of a crude oil and/or natural gas exploration and/or production well.

13. The system of claim 9 wherein the equipment is controlled by an automated closed loop control system with a selected set-point and the system is configured to automatically adjust the set point in response to the anomaly and alert an operator about the anomaly and the set-point adjustment.

14. The system of claim 9, wherein the system is configured to compare power input characteristics supplied to drilling equipment, including a mud pump, drill string hoist and top drive with delivered output drilling characteristics, including mud flux, drill string weight and rotation to alert an operator if there is an anomaly between any of the measured input and output characteristics.

15. The system of claim 11, wherein the equipment is electrically and/or hydraulically powered.

16. The method of claim 1, wherein the equipment is electrically and/or hydraulically powered and said power is electric and/or hydraulic power.

17. The method of claim 7, wherein the top drive is an electrically and/or hydraulically powered top drive.
